(19) United States
(12) Patent Application Publication
(10) Pub. No.: US 2026/0165173 A1
(43) Pub. Date: Jun. 11, 2026

(54) STACKED SUBSTRATE AND PACKAGING ASSEMBLY

(71) Applicant: PanelSemi Corporation, New Taipei City (TW)

(72) Inventors: Chin-Tang LI, New Taipei City (TW); HSIEN-TE CHEN, New Taipei City (TW); Pen-Chao LO, New Taipei City (TW)

(21) Appl. No.: 19/415,102

(22) Filed: Dec. 10, 2025

Related U.S. Application Data
(60) Provisional application No. 63/730,132, filed on Dec. 10, 2024.

(51) Int. Cl. H10W 70/685; B32B 3/14; B32B 7/022; B32B 7/027

(52) U.S. Cl. CPC H10W 70/685; B32B 3/14; B32B 7/022; B32B 7/027; B32B 2307/302; B32B 2307/54; B32B 2307/7376; B32B 2457/14

(57) ABSTRACT

A stacked substrate includes a first tiling layer, a second tiling layer and a bonding layer. The first tiling layer includes plural first tiling substrates adjacent by one another and plural first gaps formed between adjacent two first tiling substrates. The second tiling layer includes plural second tiling substrates and plural second gaps formed between adjacent two second tiling substrates. The bonding layer is arranged between the first tiling layer and the second tiling layer, and defines a first bonding surface connecting to a second surface of the first tiling substrates and a second bonding surface connecting to a first surface of the second tiling substrates. Some projections of at least some of the first gaps and some of the second gaps are offset from each other along a direction perpendicular to one or both of the first bonding surface and the second bonding surface.

### CROSS REFERENCE TO RELATED APPLICATIONS

This Non-provisional application claims priority to U.S. provisional patent application with Ser. No. 63/730,132 filed on Dec. 10, 2024. This and all other extrinsic materials discussed herein are incorporated by reference in their entirety.

### BACKGROUND

### Technology Field

The disclosure relates to a stacked substrate that can be applied to electronic packages, especially to a stacked substrate for semiconductor packages and electronic packaging assembly comprising the same.

### Description of Related Art

With the trend towards miniaturization, high performance, and high integration in electronic products, the requirements for substrate assemblies are becoming increasingly demanding. However, traditional substrate manufacturing processes face multiple challenges. For instance, to achieve cost reduction, a considerable scale of manufacturing is required, which leads to the need for large-sized substrates. However, the fabrication of large-sized substrates presents difficulties, particularly in ensuring surface flatness, where technical bottlenecks exist. Furthermore, during subsequent processes (such as packaging processes), differences in thermal expansion coefficients between materials can easily cause warpage deformation of the stacked substrate, thereby affecting product yield. In existing technology, a common approach is to use single-sized substrates for processing, but this method cannot effectively reduce manufacturing costs.

### SUMMARY

This disclosure provides a stacked substrate, which assembles a plurality of tiling substrates into a large-sized composite substrate; and the stacked substrate has a great surface flatness.

The stacked substrate of this disclosure can be segmented into a plurality of small-sized substrate, which can be applied to electronic packages.

One aspect of this disclosure is to provide a packaging assembly and one or more exemplary embodiments thereof, all of which illustrate a substrate structure of this tiled large-sized composite substrate, which can be adapted to the packaging assembly through dicing or size reduction.

This disclosure provides a stacked substrate which comprises a first tiling layer, a second tiling layer, and a bonding layer. The first tiling layer comprises a plurality of first tiling substrates adjacent by one another and a plurality of first gaps formed between adjacent two of the first tiling substrates, and the first tiling substrate defines a first surface and a second surface opposite to each other. The second tiling layer comprises a plurality of second tiling substrates adjacent to each other and a plurality of second gaps formed between adjacent two of the second tiling substrates, and the second tiling substrates defines a first surface and a second surface opposite to each other. The bonding layer is arranged between the first tiling layer and the second tiling layer, and defines a first bonding surface and a second bonding surface. The first bonding surface of the bonding layer connects the second surface of the first tiling substrates, and the second bonding surface connects to the first surface of the second tiling substrates, to connect the first tiling substrates and the second tiling substrates. At least some projections of the first gaps and the second gaps are offset from each other along a direction perpendicular to the first bonding surfaces, the second bonding surfaces, or both of the bonding layer.

In one embodiment, the first tiling substrates and the second tiling substrates respectively define one or ones edges, one or ones edges of one of at least one of the first tiling substrates approaches to one or ones edges of the corresponding second tiling substrate

In one embodiment, the first tiling substrate, the second tiling substrate, or both, comprises organic materials, inorganic materials, or a combination thereof.

In one embodiment, the first tiling substrates, the second tiling substrates, or both, comprise crystalline or amorphous silicon dioxide, glass, ceramic, compound semiconductor material, polyimide, or a combination comprising one or ones of the above-mentioned materials.

In one embodiment, the first tiling substrate and the second tiling substrate are the same material.

In one embodiment, a thermal conductivity of the first tiling substrate, the second tiling substrate, or both, is no less than 1.0 W/m*K.

In one embodiment, an elastic modulus of the first tiling substrate, the second tiling substrate, or both, is no less than 50 GPa.

In one embodiment, the stacked substrate further comprises one or ones first electrical layer structures arranged on the first surface of the first tiling substrate.

In one embodiment, the stacked substrate further comprises one or ones second electrical layer structures arranged on the second surface of the second tiling substrate.

In one embodiment, the first tiling substrate defines a first thickness, and the first surfaces of two adjacent first tiling substrates defines a height difference along a direction perpendicular to the first surface of the first tiling substrate, and the height difference is no greater than 1/10 of the first thickness of the adjacent two first tiling substrates, or the height difference is not greater than 10 μm.

In one embodiment, the first tiling substrate defines a first thickness, the second surfaces of two adjacent first tiling substrates defines a height difference along a direction perpendicular to the second surface of the first tiling substrate, and the height difference is no greater than 1/10 of the first thickness of the adjacent two first tiling substrates, or the height difference is not greater than 10 μm.

In one embodiment, the second tiling substrate defines a second thickness, and the first surfaces of two adjacent second tiling substrates defines a height difference along a direction perpendicular to the first surface of the second tiling substrate, and the height difference is no greater than 1/10 of the second thickness of the adjacent two second tiling substrates, or the height difference is not greater than 10 μm.

In one embodiment, the second tiling substrate defines a second thickness, and the second surfaces of two adjacent second tiling substrates defines a height difference along a direction perpendicular to the second surface of the second tiling substrate, and the height difference is no greater than 1/10 of the second thickness of the adjacent two second tiling substrates, or the height difference is not greater than 10 μm.

In one embodiment, the plurality of the first tiling substrates of the first tiling layer jointly defines a polished surface, and the polished surface is formed by a grinding process or a polishing process at the same time.

In one embodiment, the plurality of the second tiling substrates of the second tiling layer jointly defines a polished surface, and the polished surface is formed by a grinding process or a polishing process at the same time.

In one embodiment, the first tiling substrate defines a first thickness, the second tiling substrate defines a second thickness, and the second thickness is no less than 0.8 times of the first thickness, and no greater than 1.25 times of the first thickness.

In one embodiment, the first thickness and the second thickness is an average thickness.

In one embodiment, the bonding layer of the stacked substrate comprises inorganic materials, organic materials, or a combination thereof.

In one embodiment, the bonding layer of the stacked substrate comprises crystalline or amorphous silicon dioxide, glass, ceramic, epoxy resin, polyimide, or a combination comprising one or ones of the above-mentioned material.

In one embodiment, the bonding layer of the stacked substrate comprises glass frit, glass powder, glass paste, or a combination comprising one or ones of the above-mentioned material.

In one embodiment, a thermal conductivity of the stacked substrate is no less than a thermal conductivity of the first tiling substrate, the second tiling substrate, or both.

In one embodiment, a ratio of the thermal conductivity of the bonding layer to the thermal conductivity of the first tiling substrate, the second tiling substrate, or both is no less than 1:2.

In one embodiment, the stacked substrate further comprises a plurality of through holes penetrating through the first tiling substrates, the bonding layer and the corresponding second tiling substrates.

In one embodiment, the stacked substrate further comprises a plurality of conductive materials arranged in at least some of the through holes and electrically connect the first surface of the first tiling substrates and the second surface of the second tiling substrates.

In one embodiment, the bonding layer of the stacked substrate is a thermal conducting layer or comprises a thermal conducting layer; the thermal conducting layer comprises conductive thermal conducting materials, conductive thermal conducting particles, or a combination thereon, and the thermal conducting layer is insulated from the conductive materials in the through holes.

In one embodiment, the thermal conducting layer is arranged at one lateral of at least one of the first tiling layer or the second tiling layer, and the thermal conducting layer is a metal layer or comprises metal material.

In one embodiment, the bonding layer of the stacked substrate is a thermal conducting layer or comprises the thermal conducting layer, and the thermal conducting layer comprises non-conductive thermal conducting material, thermal conducting particles, or a combination thereof.

In one embodiment, the thermal conducting layer comprises carbon nanotube, graphene, or a combination thereof.

In one embodiment, the thermal conducting layer is arranged at one lateral of at least one of the first tiling layer or the second tiling layer, and comprise silicon carbide (SiC) particles, silicon (Si) particles, or a combination thereof.

In one embodiment, the bonding layer defines a bonding layer thickness, the first tiling substrate defines a first thickness, and the bonding layer thickness is no greater than 1/10 of the corresponding first thickness of the first tiling substrate.

In one embodiment, the bonding layer defines a bonding layer thickness, the second tiling substrate defines a second thickness, and the bonding layer thickness is no greater than 1/10 of the corresponding second thickness of the second tiling substrate.

In one embodiment, the bonding layer defines a bonding layer thickness, the first tiling substrate defines a first thickness, the second tiling substrate defines a second thickness, and the bonding layer thickness is no greater than 1/10 of the corresponding first thickness of the first tiling substrate and 1/10 of the second thickness of the second tiling substrate.

In one embodiment, the bonding layer thickness is no greater than 50 μm.

In one embodiment, the bonding layer thickness is no greater than 10 μm.

In one embodiment, the stacked substrate further comprises a gap filling material which is arranged in at least some of the first gaps and the second gaps.

In one embodiment, the filling material comprises organic material, inorganic material, or both.

In one embodiment, the filling material comprises crystalline or amorphous silicon dioxide, glass, ceramic, epoxy resin, polyimide, or a combination comprising one or ones of the above-mentioned material.

In one embodiment, an elastic modulus of the filling material is less than the elastic modulus of a corresponding first tiling substrate, or less than the elastic modulus of a corresponding second tiling substrate.

In one embodiment, two first surfaces of two adjacent first tiling substrates, and the filling material arranged between the two first surfaces, defines a height difference along a direction perpendicular to the first surface of the first tiling substrate and the height difference is no greater than 1/10 of the thickness of the two adjacent first tiling substrates.

In one embodiment, two second surfaces of two adjacent first tiling substrates, and the filling material arranged between the two second surfaces, defines a height difference along a direction perpendicular to the second surface of the first tiling substrate and the height difference is no greater than 1/10 of the thickness of the two adjacent first tiling substrates.

In one embodiment, two first surfaces of two adjacent first tiling substrates, and the filling material arranged between the two first surfaces, defines a height difference along a direction perpendicular to the first surface of the first tiling substrate and the height difference is no greater 10 μm.

In one embodiment, two second surfaces of two adjacent first tiling substrates, and the filling material arranged between the two second surfaces, defines a height difference along a direction perpendicular to the second surface of the first tiling substrate and the height difference is no greater 10 μm.

In one embodiment, two first surfaces of two adjacent second tiling substrates, and the filling material arranged between the two first surfaces, defines a height difference along a direction perpendicular to the first surface of the second tiling substrate and the height difference is no greater than 1/10 of the thickness of the two adjacent second tiling substrates.

In one embodiment, two second surfaces of two adjacent second tiling substrates, and the filling material arranged between the two second surfaces, defines a height difference along a direction perpendicular to the second surface of the second tiling substrate and the height difference is no greater than 1/10 of the thickness of the two adjacent second tiling substrates.

In one embodiment, two first surfaces of two adjacent second tiling substrates, and the filling material arranged between the two first surfaces, defines a height difference along a direction perpendicular to the first surface of the second tiling substrate and the height difference is no greater 10 μm.

In one embodiment, two second surfaces of two adjacent second tiling substrates, and the filling material arranged between the two second surfaces, defines a height difference along a direction perpendicular to the second surface of the second tiling substrate and the height difference is no greater 10 μm.

In one embodiment, the first tiling substrates of the first tiling layer and the filling materials arranged between jointly define a polished surface, and the polished surface is formed by a grinding process or a polishing process at the same time.

In one embodiment, the second tiling substrates of the second tiling layer and the filling materials arranged between jointly define a polished surface, and the polished surface is formed by a grinding process or a polishing process at the same time.

In one embodiment, a thickness of the gap filling material is essentially the same of the thickness of the corresponding first tiling substrate or the corresponding second tiling substrate.

In one embodiment, the stacked substrate defines a plurality of tiling units, and the tiling unit is surrounded by some of the first gaps, some of the second gaps, or both, and the tiling unit dose not comprises the first gaps or the second gaps therein; each of the tiling units includes one or ones of dicing units.

In one embodiment, at least one of the tiling units defines an area no less than 5000 mm².

In one embodiment, at least one of the dicing units defines an area no less than 5000 mm².

In one embodiment, an area difference of two areas of at least one of the first tiling substrates at two laterals where the first tiling substrates across a corresponding second gap is no greater than 10%

In one embodiment, the first tiling substrate defines a first coefficient of thermal expansion (CTE), the second tiling substrate defines a second coefficient of thermal expansion, and a difference between the first coefficient of thermal expansion and the second coefficient of thermal expansion is no greater than 5 ppm/K.

In one embodiment, the bonding layer defines a third coefficient of thermal expansion, and a difference between the third coefficient of thermal expansion and the first coefficient of thermal expansion is no greater than 30 ppm/K.

In one embodiment, the bonding layer defines a third coefficient of thermal expansion, and a difference between the third coefficient of thermal expansion and the first coefficient of thermal expansion is no greater than 10 ppm/K.

In one embodiment, the stacked substrate further comprises a gap filling material arranged in at least some of the first gaps and the second gaps; the gap filling material defines a fourth coefficient of thermal expansion, and a difference between the first coefficient of thermal expansion and the fourth coefficient of thermal expansion is no greater than 30 ppm/K.

In one embodiment, the gap filling material and the bonding layer are made of or made from a same material.

In one embodiment, the first gap defines a first width, the second gap defines a second width, and the first width, the second width, or both is no less than 50 μm.

This disclosure also provides an packaging assembly, which comprises a portion of the above-mentioned stacked substrate; the stacked substrate defines a plurality of tiling units, each of the tiling units is surrounded by some of the first gaps and some of the second gaps and the tiling unit does comprises the first gaps and the second gaps therein; each of the tiling units includes one or ones dicing units; wherein the portion of the stacked substrate at least includes one or ones of the dicing units.

In one embodiment, one or ones of the tiling unit defines an area no less than 5000 mm².

In one embodiment, one or ones of the dicing units defines an area no less than 5000 mm².

Accordingly, the stacked substrate of the present invention comprises two tiling layers, and the two tiling layers are respectively tiles by a plurality of tiling substrates. A plurality of gaps are formed between the tiling substrates, and the gaps of the two tiling layers are off-set so as to increase physical strength of the stacked substrate. The gaps can serve as cutting sites for subsequent processing of the stacked substrate which improves convenience of the manufacturing process.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1A to FIG. 1G are schematic diagrams showing an embodiment of this invention;

FIG. 2A to FIG. 2C is are schematic diagrams showing another embodiment of this invention;

FIG. 3A and FIG. 3B are schematic diagrams showing the relative relations of the tiling substrates and the gap filling material of this invention;

FIG. 4A and FIG. 4B are schematic diagrams showing two other embodiments of this invention;

FIG. 5A to FIG. 5C are schematic diagrams showing one manufacturing process of FIG. 4A;

FIG. 6A to FIG. 6C are schematic diagrams showing one manufacturing process of FIG. 4B;

FIG. 7A and FIG. 7B are schematic diagrams showing two other embodiments of this invention;

FIG. 8A and FIG. 8B are schematic diagrams showing two other embodiments of this invention.

FIG. 9 is a schematic diagram showing a packaging assembly of this invention;

FIG. 10A and FIG. 10 B are schematic diagrams showing one embodiment of this invention and a packaging assembly using the same;

FIG. 11A and FIG. 11B are schematic diagrams showing two other embodiments of this invention; and

FIG. 12A and FIG. 12B are schematic diagrams showing two packaging assemblies containing a portion of this invention in FIG. 11A and FIG. 11B.

### DETAILED DESCRIPTION OF THE DISCLOSURE

The foregoing is merely illustrative and not intended to limit the disclosure. In addition to the illustrative embodiments, examples, and features described above, other embodiments, examples, and features of the disclosure can be clearly understood by referring to the drawings and the following detailed description.

The following description will refer to relevant drawings to explain the stacked substrate according to the preferred embodiments of this invention, wherein the same elements will be described using the same reference symbols.

The advantages, features, and implementation methods of this disclosure will be clearly explained in the following embodiments with reference to the drawings. However, this disclosure may be embodied in various forms and should not be construed as being limited to the embodiments described herein. Rather, these embodiments are provided to make this specification thorough and complete, and to fully convey the scope of the disclosure to those skilled in the art. The scope of this disclosure should be defined only by the appended claims. Therefore, well-known components, operations, and techniques are not described in detail in the embodiments to avoid obscuring the technical features of the disclosure. Throughout the specification, identical or similar elements are denoted by identical or similar reference symbols. When an element is referred to as being “connected” to another element, it may be “directly or indirectly mechanically connected” to, or “electrically connected” to the other element, and one or more intervening elements may be present therebetween. It is to be understood that in this specification, the terms “include” or “comprise” specify the stated features, integers, steps, operations, elements and/or components, but do not preclude the presence or addition of one or more other features, integers, steps, operations, elements and/or components, or any combination thereof. The term “and/or” or “or/and” indicates the possibility of intersection or union of one or more other features, integers, steps, operations, elements and components, or any combination thereof. Unless otherwise defined, all terms used in this specification (including technical and scientific terms) have the same meanings as commonly understood by those skilled in the art to which this disclosure pertains. Further, terms, including those defined in commonly used dictionaries, should be interpreted as having meanings consistent with their meaning in the context of the relevant art and will not be interpreted in an idealized or overly rigorous sense unless explicitly defined herein.

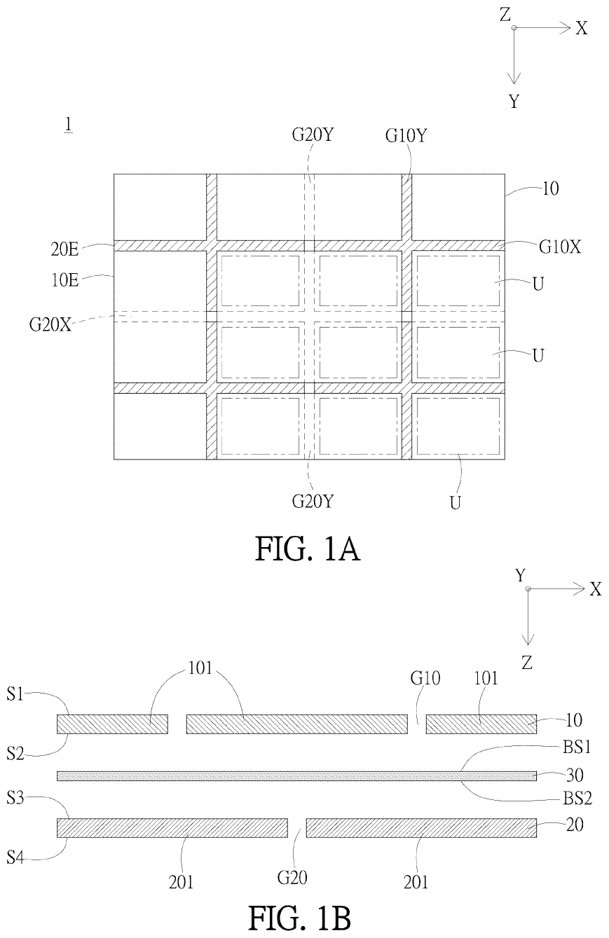

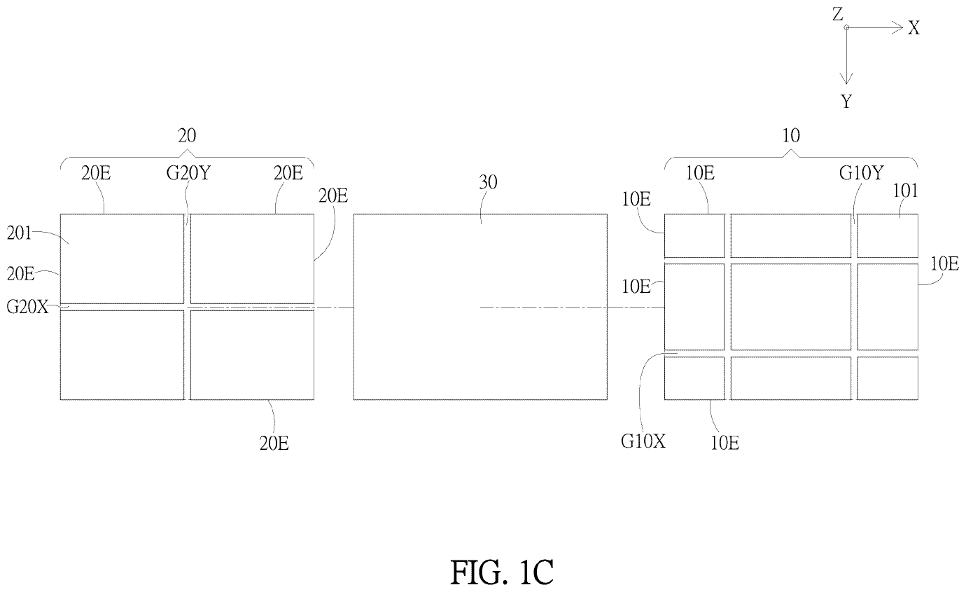

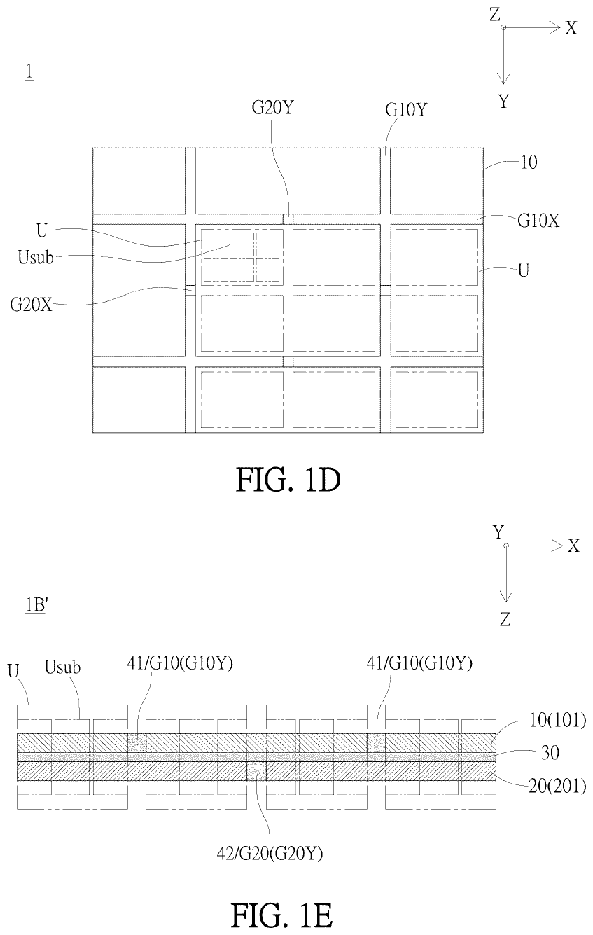

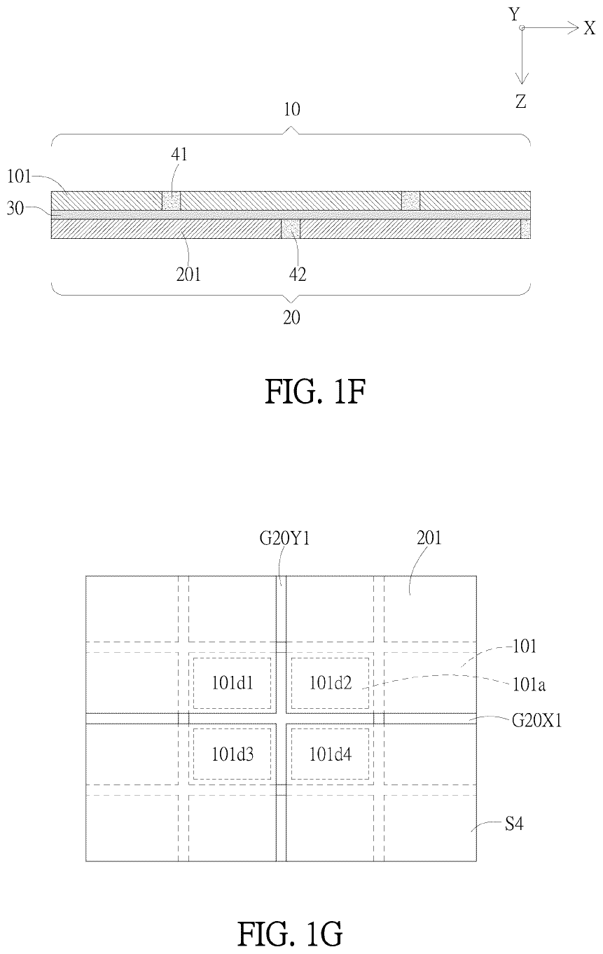

Referring to FIGS. 1A, FIG. 1B, and FIG. 1C, show an embodiment of a stacked substrate 1. The stacked substrate 1 includes a first tiling layer 10, a second tiling layer 20, and a bonding layer 30. The first tiling layer 10 includes a plurality of first tiling substrates 101101 adjacent to one another and a plurality of first gaps G10 (G10X, G10Y) formed between adjacent two of the first tiling substrates 101. Each of the first tiling substrates 101 defines a corresponding first surface S1 and a second surface S2. The second tiling layer 20 includes a plurality of second tiling substrates 201 adjacent to one another and a plurality of second gaps G20 (G20X, G20Y) formed between adjacent two of the second tiling substrates 201. Each of the second tiling substrates 201 defines a corresponding first surface S3 and a second surface S4. The bonding layer 30 connects the first and second tiling layers 10, 20; the bonding layer defines a first bonding surface BS1 and a second bonding surface BS2, the first bonding surface BS1 connects to the second surface S2 of the first tiling substrates 101, and the second bonding surface BS2 connects to the first surface S3 of the second tiling substrates 201, which indicated that the bonding layer 30 connects the first surface S3 of each of the second tiling substrates 201 to the second surface S2 of a corresponding one of the first tiling substrates 101, to connect the first tiling layer 10 and the second tiling layer 20. The bonding layer 30 can be a continuous or discontinuous arranged between the first and second tiling layers 10, 20, and defines a planar direction (formed by X-axis direction and Y-axis direction); along a direction Z perpendicular to the first bonding surface BS1, the second bonding surface BS, or both of the bonding layer 30, projections of at least some of the first gaps (G10X, G10Y) and the second gaps (G20X, G20Y) are offset from each other. The first tiling substrates 101 and the second tiling substrates 201 respectively define one or more edges 10E, 20E; the first tiling layer 10 and the second tiling layer 20 respectively defines a contour formed by corresponding ones of the edges 10E, 20E thereof; the contour of the first tiling layer 10 approaches to the contour of the second tiling layer 20, such that one or ones edges 10E of one of the first tiling substrates 101 approach to one or ones of the edges 20E of the corresponding one of the second tiling substrates 201, to maximize the area ca be utilized. The stacked substrate 1 further defines a plurality of tiling units U; wherein each tiling unit U is surrounded by some of the first gaps G10 (G10X, G10Y), some of the second gaps G20 (G20X, G20Y), or both. Each of the tiling units U does not comprise the first gaps G10 (G10X, G10Y) and second gaps G20 (G20X, G20Y) therein. In some embodiments, the first gaps G10 (G10X, G10Y), the second gaps G20 (G20X, G20Y), or both, define a width no less than 50 μm. Each of the tiling units U includes one or more dicing units, in FIGS. 1A, each of the tiling units 1U only includes a single dicing unit; in FIG. 1D or 1E, each of the tiling units U includes multiple dicing units Usub. In some embodiments, at least one of the tiling units U defines an area no less than 5000 mm²; in some embodiments, the dicing unit(s) Usub define(s) an area no less than 5000 mm². The planar sizes of the first tiling substrates 101 and second tiling substrates 201 can be adjusted according to requirements, and the area of adjacent two of the first tiling substrates 101, or adjacent two of the second tiling substrates 201 may also be different. One aim of this disclosure is to approach the contour of the first tiling layer 10 to the contour of the second tiling layer 20 by a tiling process. Further, two tiling units U can by separated by a dicing process, and the cutting sites can be located in the first and second gaps G10, G20, or the cutting sites can be located with the first tiling substrates 101 or the second tiling substrates 201 near the first and second gaps G10, G20.

In some embodiments, the stacked substrate 1 further includes a gap filling material 41, 42, as shown in FIG. 1F, the gap filling material 41, 42 is arranged in at least some of the first gaps G10 (G10X, G10Y) and the second gaps G20 (G20X, G20Y). The gap filling materials 41, 42 and the bonding layer 30 may be made of or made from the same material, but are not limited thereto.

In FIG. 1A to FIG. 1F, projections of the second tiling substrates 201 along the first surfaces S3 of the second substrates 202 overlap at a least partial of the a plurality (at least two) of the first tiling substrates 101, therefore, the first gaps (G10X, G10Y) and the second gaps (G20X, G20Y) of the first tiling layer 10 and the second tiling layer 20, which is respectively tiles by a plurality of first tiling substrates 101 and a plurality of second tiling substrates 201, are off-set from each other along a direction perpendicular to the first surface S3 of the second tiling substrate 201.

Referring to FIG. 1G, in one embodiment, a first tiling substrate 101a of the first tiling layer 10 is arranged across on four corresponding second tiling substrates 201. In this embodiment, the projection sites of the second gaps G20Y1, G20X1 of the second tiling layer 20 along a direction perpendicular to the first surface S3 or the second surface S4 of the second tilling substrate of the second tiling layer 20 on the first tiling substrate 101a, divide the first tiling substrate 101a into four regions (101a1, 101a2, 101a3, and 101a4). The area of each of the four regions 101a1, 101a2, 101a3, and 101a4 is similar, ex. the difference between the area of the four regions is not greater than 10%, but not limited there to.

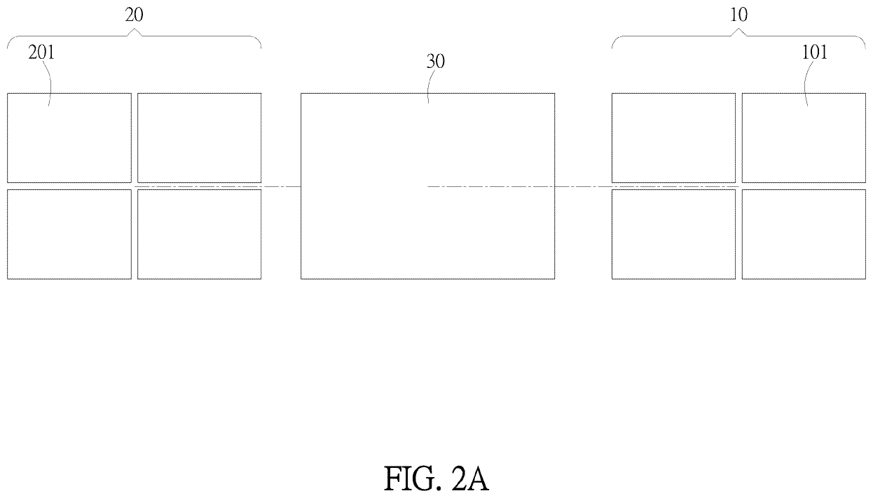

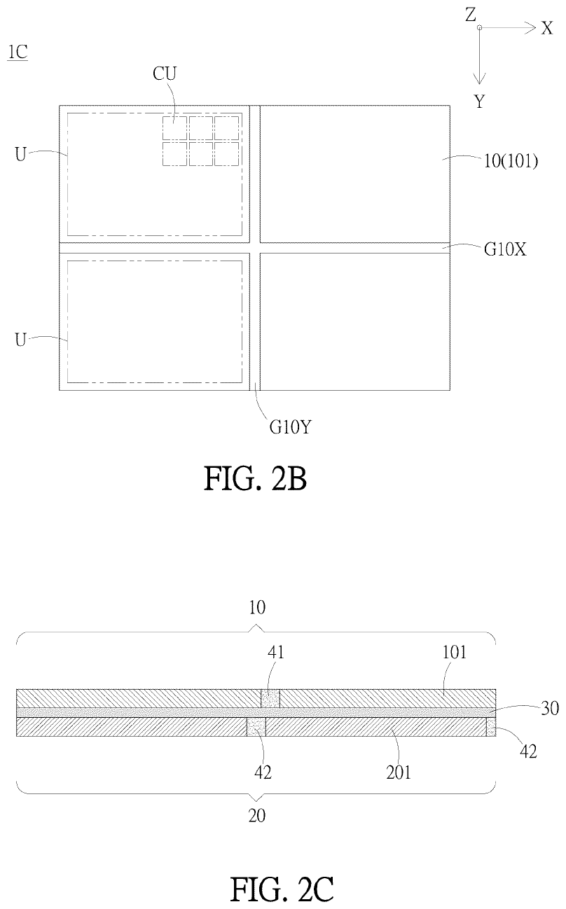

Referring to FIG. 2A, in this embodiment, the first tiling layer 10 comprises four first tiling substrates 101 with the same area, and the second tiling layer 20 comprises four second tiling substrates 201 with the same area. After tiling of the four first tiling substrates 101 and the four second tiling substrates 201, the first gaps G10X, G10Y and the second gaps G20X, G20Y are formed. The gap filling material 41, 42 are respectively arranged in the first gaps G10X, G10Y and the second gaps G20X, G20Y. Referring to FIG. 2B, the first tiling layer 10 defines one or ones of tiling unit U, and the tiling units U further defined a plurality of dicing units Usub. A cutting site (or cutting path) is defined between two adjacent tiling units U; the cutting site (cutting path) can located on the first gaps G10X, G10Y or/and the second gaps G20X, G20Y; in other cases, the cutting site (cutting path) can located at a site(path) near to but not on the first gaps G10X, G10Y or/and the second gaps G20X, G20Y.

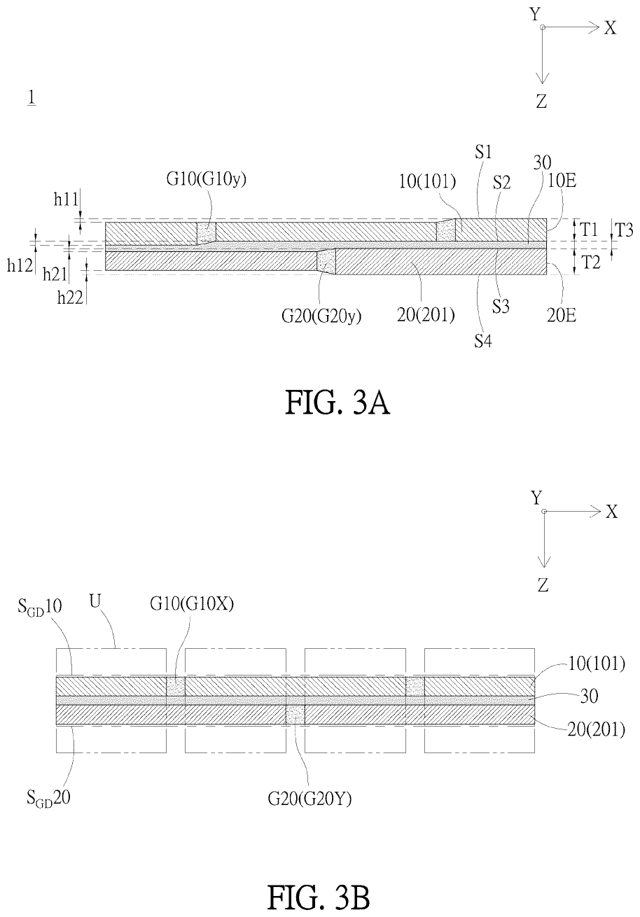

Referring to FIG. 3A, the first tiling substrates 101 define a first thickness T1, and the second tiling substrates 201 define a second thickness T2. In some embodiments, the first thickness T1 is between 0.8 to 1.25 times of the second thickness T2, and in some other embodiments, the second thickness T2 is between 0.8 to 1.25 times of the first thickness T1. The first thickness T1 and the second thicknesses T2 can be an average thicknesses. In some embodiments, a height difference h11 is defined between two first surfaces S1 of adjacent two of the first tiling substrates 101 along a direction Z perpendicular to the first surface S1, wherein the height difference h11 is 1/10 of the first thickness T1 of one of the adjacent two first tiling substrates 101, or the height difference h11 is no greater than 1/10 of the first thickness T1 of one of the adjacent two first tiling substrates 101, or the height difference h11 is no greater than 10 μm. In some embodiments, a height difference h12 is defined between two second surfaces S2 of adjacent two of the first tiling substrates 101 along the direction Z perpendicular to the second surfaces S2 of the first tiling substrates 101, wherein the height difference h12 is 1/10 of the first thickness T1 of one of the adjacent two first tiling substrates 101, or the height difference h12 is no greater than 1/10 of the first thickness T1 of one of the adjacent two first tiling substrates 101, or the height difference h12 is not greater than 10 μm. In some embodiments, a height difference h21 is defined between two first surfaces S3 of adjacent two of the second tiling substrates 201 along the direction Z perpendicular to the first surfaces S3 of the second tiling substrates 201, wherein the height difference h21 is 1/10 of the second thickness T2 of one of the adjacent two second tiling substrates 201, or the height difference h21 is no greater than 1/10 of the second thickness T2 of one of the adjacent two second tiling substrates 201, or the height difference h21 is not greater than 10 μm. In some embodiments, a height difference h22 is defined between two second surfaces S4 of adjacent two of the second tiling substrates 201 along the direction Z perpendicular to the second surfaces S4 of the second tiling substrates 201, wherein the height difference h22 is 1/10 of the second thickness T2 of one of the adjacent two second tiling substrates 201, or the height difference h22 is no greater than 1/10 of the second thickness T2 of one of the adjacent two second tiling substrates 201, or the height difference h22 is not greater than 10 μm. In some embodiments, the bonding layer 30 defines a thickness T3, the thickness T3 is no greater than 1/10 of the thickness T1 of the first tiling substrate 101 and/or the thickness T20 of the second tiling substrate 201. In some embodiments, the thickness T3 is no greater than 50 μm, or the thickness T30 is no greater than 10 μm.

In some embodiments, a height difference is defined between the gap filling material 41 and the first surfaces S1 of adjacent one of the first tiling substrates 101 along the direction Z perpendicular to the first surfaces S1 of the first tiling substrates 101, the height difference is not greater than 1/10 of the first thickness T1 of the adjacent one of the first tiling substrates 101, or the height difference is not greater than 10 μm. In some embodiments, a height difference is defined between the gap filling material 41 and the second surfaces S2 of adjacent one of the first tiling substrates 101 along the direction Z perpendicular to the second surfaces S2 of the first tiling substrates 101, the height difference is not greater than 1/10 of the first thickness T1 of the adjacent one of the first tiling substrates 101, or the height difference is not greater than 10 μm. In some embodiments, a height difference is defined between the gap filling material 42 and the first surfaces S3 of adjacent one of the second tiling substrates 201 along the direction Z perpendicular to the first surfaces S3 of the second tiling substrates 201, the height difference is not greater than 1/10 of the second thickness T2 of the adjacent one of the second tiling substrates 201, or the height difference is not greater than 10 μm. In some embodiments, a height difference is defined between the gap filling material 42 and the second surfaces S4 of adjacent one of the second tiling substrates 201 along the direction Z perpendicular to the second surfaces S4 of the second tiling substrates 201, the height difference is not greater than 1/10 of the second thickness T2 of the adjacent one of the second tiling substrates 201, or the height difference is not greater than 10 μm. In some embodiments, the gap filling materials 41, 42 define a thickness that is essentially the same with the thickness T1 or T2 of their corresponding one of the first tiling substrates 101 or second tiling substrates 201. Referring to FIG. 3B, in some embodiments, the outward-facing surfaces of adjacent two first tiling substrate 101 (the first surface S1) jointly define a polished surface SGD10, and the outward-facing surfaces of adjacent two second tiling substrate 201 (the second surface S4) jointly define a polished surface SGD20. The polished surfaces SGD10, SGD20 may respectively include the gap filling materials 41, 42. To lower the height difference between the adjacent first tiling substrates 101, the adjacent second tiling substrates 201 and the corresponding gap filling materials 41, 42, even making these height differences approaching to zero, a grinding process or/and a polishing process is applied to the first tiling substrates 101, the second tiling substrates 201, and the gap filling materials 41, 42 in the gaps for planarization, thus the flatness of the polished surfaces SGD10, SGD20 is increased. A high flatness of the surface can lower the risk of product quality and yield due to excessive height difference during subsequent process for forming circuit and patterns on the first tiling substrates 101 and or the second tiling substrates 201.

In some embodiments, the first tiling substrates and/or the second tiling substrates include inorganic materials, organic materials, or a combination thereof; for example, the first tiling substrates and/or the second tiling substrates include crystalline or amorphous silicon dioxide (SiO₂), glass, ceramic, compound semiconductor material, polyimide, or a combination includes one or ones of the above-mentioned materials. In some embodiments, the first tiling substrates and the second tiling substrates are made of or made from the same material. In some embodiments, the first tiling substrates and/or the second tiling substrates define a thermal conductivity no less than 1.0 W/m*K. In some embodiments, the first tiling substrates and/or the second tiling substrates defines an elastic modulus no less than 50 GPa (Gigapascal). In some embodiments, the first tiling substrates define a first coefficient of thermal expansion, and the second tiling substrates define a second coefficient of thermal expansion; a difference between the first coefficient of thermal expansion and the second coefficient of thermal expansion is no greater than 5 ppm/K. In some embodiments, the bonding layer 30 defines a third coefficient of thermal expansion, and a difference between the first coefficient of thermal expansion and the third coefficient of thermal expansion is no greater than 30 ppm/K, or no greater than 10 ppm/K. In some embodiments, the gap filling materials 41, 42 define a fourth coefficient of thermal expansion, and a difference between the first coefficient of thermal expansion and the fourth coefficient of thermal expansion is no greater than 30 ppm/K. The above-mentioned coefficient of thermal expansion ranges from 25° C. to 400° C., and the recommended CTE difference is intended to reduce the risk of warpage.

In some embodiments, the bonding layer 30 includes inorganic material, organic material, or a combination; for example, the bonding layer 30 comprises crystalline or amorphous silicon dioxide (SiO₂), glass, ceramic, or epoxy resin, polyimide, or a combination includes one or ones of the above-mentioned materials. In some embodiments, the bonding layer 30 comprises glass frit, glass powder, glass paste, or a combination includes one or ones of the above-mentioned materials. Adding the inorganic materials in to the bonding layer can further change the characters of the bonding layer 30, such as lowering coefficient of thermal expansion, increasing physical strength and moisture resistance. In some embodiments, the thermal conductivity of the bonding layer 30 is no less than a thermal conductivity of the first tiling substrates 101 and second tiling substrates 201. Furthermore, the thermal conductivity of the bonding layer 30 is no less than two times of the thermal conductivity of the first tiling substrate 101 and the second tiling substrates 201.

In some embodiments, the gap filling materials 41, 42 include inorganic materials, organic materials, or a combination; for example, the gap filling materials 41, 42 include crystalline or amorphous silicon dioxide (SiO₂), glass, ceramic, or epoxy resin, polyimide, or a combinations including one or ones of the above-mentioned materials. Adding the inorganic materials into the gap filling materials 41, 42 can change the characters of the gap filling materials 41, 42, such as lowering coefficient of thermal expansion, increasing physical strength and moisture resistance. In some embodiments, an elastic modulus of the gap filling materials 41, 42 is less than an elastic modulus of a corresponding one of the first tiling substrates 101 or the second tiling substrates 201, to further reduce the risk of warpage.

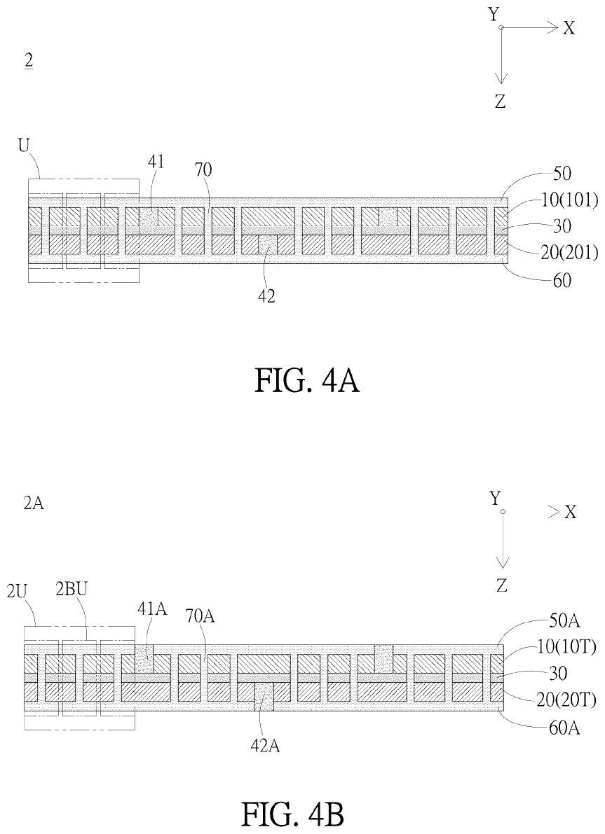

Please refer to FIG. 4A, the stacked substrate 2 includes one or more first electrical layer structures 50 arranged at a lateral of the first tiling layer 10 opposite to the bonding layer 30. The stacked substrate 2 may include one or more second electrical layer structures 60 arranged at a lateral of the second tiling layer 20 opposite to the bonding layer 30. In some embodiments, the stacked substrate 2 only include the first electrical layer structures 50, or only includes the second electrical layer structures 60. In some embodiments, the stacked substrate 2 includes both of the first electrical layer structures 50 and the second electrical layer structures 60 In FIG. 4A, the first and second electrical layer structures 50, 60 respectively covers on the gap filling material 41 between adjacent two first tiling substrates 101 and the gap filling material 42 between adjacent two second tiling substrates 201. In FIG. 4A2, the stacked substrate 2 may further include a plurality of conductive through holes 70, the conductive through holes 70 penetrate through the first tiling substrates 101, the bonding layer 30, and the second tiling substrates 201, and the conductive through holes 70 connect the first surface S1 of the first tiling substrates 101 with the second surface S4 of the second tiling substrates 201; the conductive through holes 70 also electrically connect the first electrical layer structures 50 and second electrical layer structures 60. Referring to FIG. 4B, the structure of the stacked substrate 2A is similar to the stacked substrate 2 in FIG. 4A, the difference therebetween is the first and second electrical layer structures 50, 60 of the stacked substrate 2A are only arranged on the outer surfaces of the first tiling substrates 101 and the outer surfaces of adjacent two second tiling substrates 201, but do not cover on the gap filling materials 41, 42, in other words, the gap filling materials 41, 42 is exposed on the outer surfaces of the first and second electrical layer structures 50, 60.

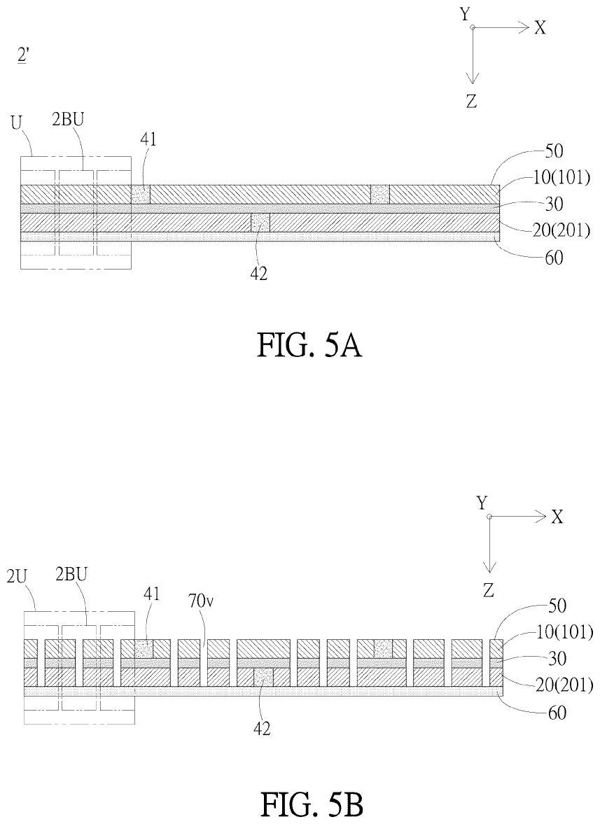

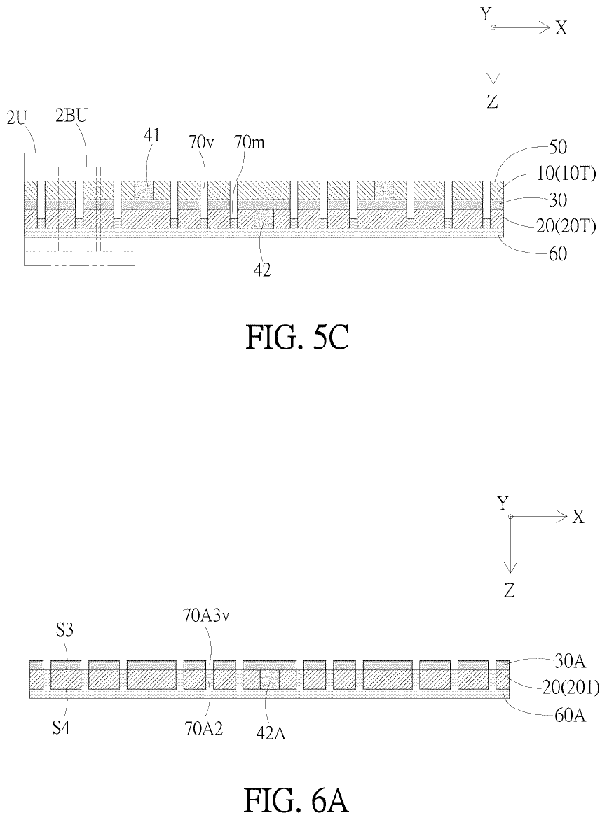

FIG. 5A, FIG. 5b, and FIG. 5C illustrate one of the manufacturing processes of the stacked substrate 2 in FIG. 4A, but this embodiment is only for exemplary. In FIG. 5A, the first and second tiling layers 10, 20 are connected to each other by the bonding layer 30, and the gap filling materials 41, 42 are arranged in the gaps between the tiling substrates, then the first and second electrical layer structures 50, 60 are formed or arranged on an outer surface of the first tiling layer 10 and the second tiling layer 20, and the order to form or manufacture the first and second electrical layer structures 50, 60 is not limited, and, the second electrical layer structure 60 is formed or arranged first in this embodiment. In FIG. 5B, a through-hole process is then performed in the substrate structure in FIG. 5A, and a plurality of through holes 70v penetrating through the first tiling substrates 101, the bonding layer 30, and the second tiling substrates 201 is formed. Referring to FIG. 5C, a conductive material 70m is then arranged in at least some of the through holes 70v shown in FIG. 5B to form the conductive through holes 70, and the first surface S1 of the first tiling substrates 101 is connected with the second surface S4 of the second tiling substrates 201, thereby electrically connecting to the second electrical layer structure 60. After arranging the conductive material 70m in the through holes 70v, the first electrical layer structure 50 is then formed or arranged on the first surface S1 of the first tiling substrates 101, thereby electrically connecting to the second electrical layer structure 60 by the conductive through holes 70. It is noted that, the above-mentioned processes is only one processes for arranging the conductive through holes 70, but is not limited thereto. In another processes, the conductive through holes 70 can be manufactured in the first and second tiling layer before arranging the first and the second electrical layer structures 50, 60.

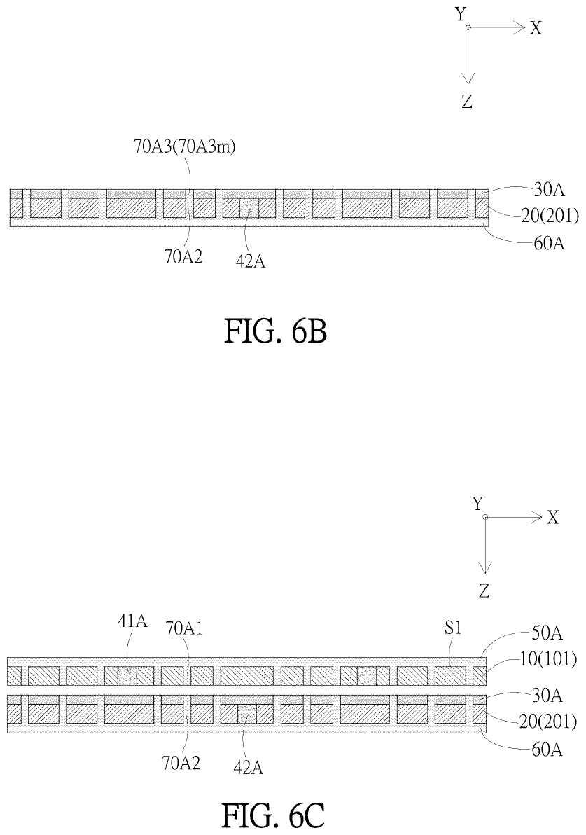

FIG. 6A, FIG. 6B, and FIG. 6C illustrate one of the manufacturing processes for forming the stacked substrate 2A of FIG. 4B. In FIG. 6A, the second electrical layer structure 60A and multiple conductive through holes 70A2 has arranged on the second surface S4 of the second tiling layer 20 and in the second tiling layer 20, and these conductive vias 70A2 connect the first surface S3 and the second surface S4 of the second tiling substrates 201, thereby electrically connecting to the second electrical layer structure 60A; then the bonding layer 30A is arranged on the first surface S3 of the second tiling layer 20, and the gap filling material 42A is arranged in the gaps between the plurality of the second tiling substrates 201, the order to arrange the bonding layer 30A and the gap filling material 42A is not limited. Then, multiple through holes 70A3v are formed corresponding to these conductive through holes 70A2 in the bonding layer 30A. In FIG. 6B, a conductive material 70A3m is then arranged in the through holes 70A3v shown in FIG. 6A to form these conductive through holes 70A3. These conductive vias 70A3 electrically connect to the corresponding conductive through holes 70A2, and connect to a surface of the bonding layer opposite to the second tiling layer 20. In FIG. 6C, the first tiling layer 10 with the first electrical layer structure 50A and a plurality of the conductive through holes 70A1 is then bonded to the surface of the bonding layer opposite to the second tiling layer 20 shown in FIG. 6B. The first electrical layer structure 50A is arranged on the first surface of the first tiling layer, and these conductive through holes 70A1 connect the first surface S1 and second surface S2 of the first tiling substrates 101, thereby electrically connecting to the first electrical layer structure 50A. The conductive through holes 70A1 of the first tiling layer 10 correspond to and electrically connect to the conductive through holes 70A3 in FIG. 6B, thereby forming the conductive vias 70A in the stacked substrate 2A in FIG. 4B.

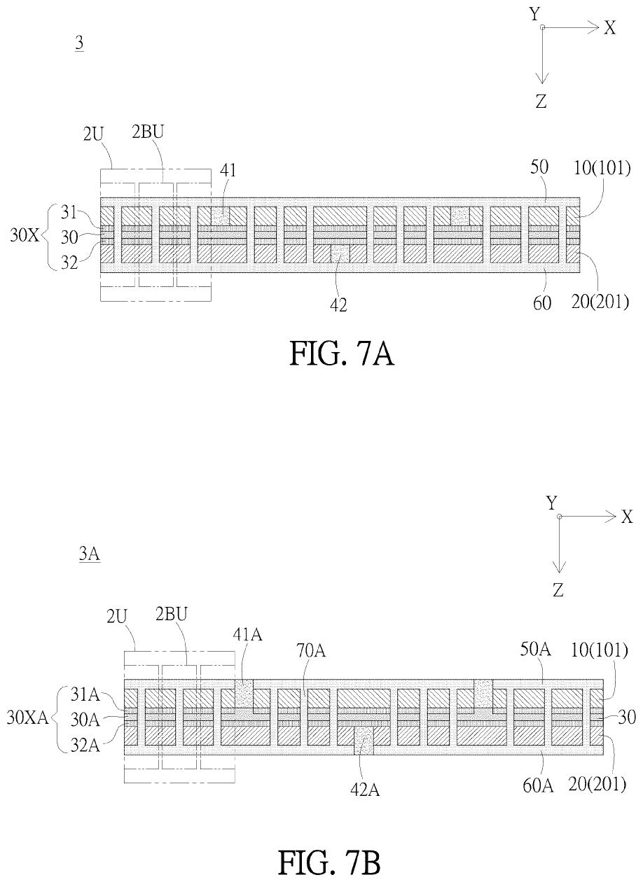

In some embodiments, the bonding layer of the stacked substrate is or includes a thermal-conducting layer, which comprises conductive or non-conductive thermal-conducting materials and/or thermal-conducting particles. Referring to FIG. 7A and FIG. 7B, the bonding layer can serve as a composite bonding structure 30X which comprises a bonding layer 30 and two thermal-conducting layers 31, 32 arranged at two laterals of the bonding layer 30. The thermal-conducting layers 31 is arranged between the bonding layer 30 and the first tiling substrates 101, and the thermal-conducting layers 32 is arranged between the bonding layer 30 and the second tiling substrates 201. The thermal-conducting layers 31, 32 can be pre-arranged on two laterals of the bonding layer 30, or the thermal-conducting layers 31, 32 can be pre-arranged on their corresponding first tiling substrates 101 and second tiling substrates 201. The stacked substrate 3A in FIG. 7B has a similar structure to the stacked substrate 3 in FIG. 7A, but the thermal-conducting layers 31, 32 is pre-arranged at two laterals of the bonding layer 30 in the composite bonding structure 30X of the stacked substrate 3 in FIG. 7A, so the location on the bonding layer 30 corresponding to the gap filling material 41, 42 are covered by the thermal-conducting layers 31, 32. For the stacked substrate 3A, the thermal-conducting layers 31A, 32A of the composite bonding structure 30XA are pre-arranged on the corresponding first tiling substrates 101 and second tiling substrates 201, therefore the location on the bonding layer 30 corresponding to the gap filling material 41, 42 are not covered. The thermal-conducting layers 31, 32 and thermal-conducting layers 31A, 32A in FIG. 7A and FIG. 7B are non-conductive thermal-conducting materials and/or thermal-conducting particles, for example, carbon nanotubes and/or graphene, and/or multiple silicon carbide (SiC) and/or silicon (Si) thermal-conducting particles.

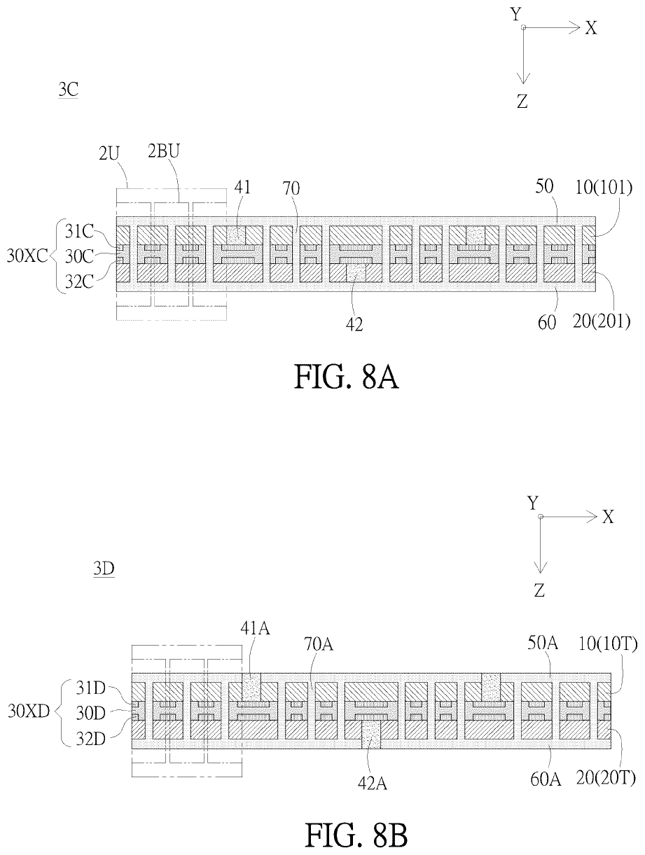

Referring to FIG. 8A and FIG. 8B, the stacked substrates 3C and 3D have a similar structure to the stacked substrates 3 and 3A in FIG. 7A and FIG. 7B. However, the thermal-conducting layer 31C, 32C of the stacked substrates 3C and the thermal-conducting layer 31D, 32D of the stacked substrates 3D are or comprises conductive thermal-conducting materials and/or thermal-conducting particles, and the thermal-conducting layers 31C, 32C and thermal-conducting layers 31D, 32D are insulated from the conductive through holes 70A due to the no contact between the conducting layers 31C, 32C, 31D, 32D and the conductive through holes 70A. The thermal-conducting layers 31C, 32C and thermal-conducting layers 31D, 32D can be a metal layer or include a plurality of metal particles.

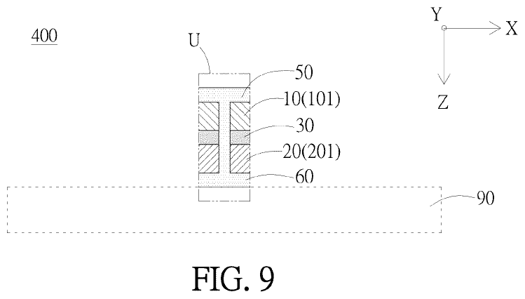

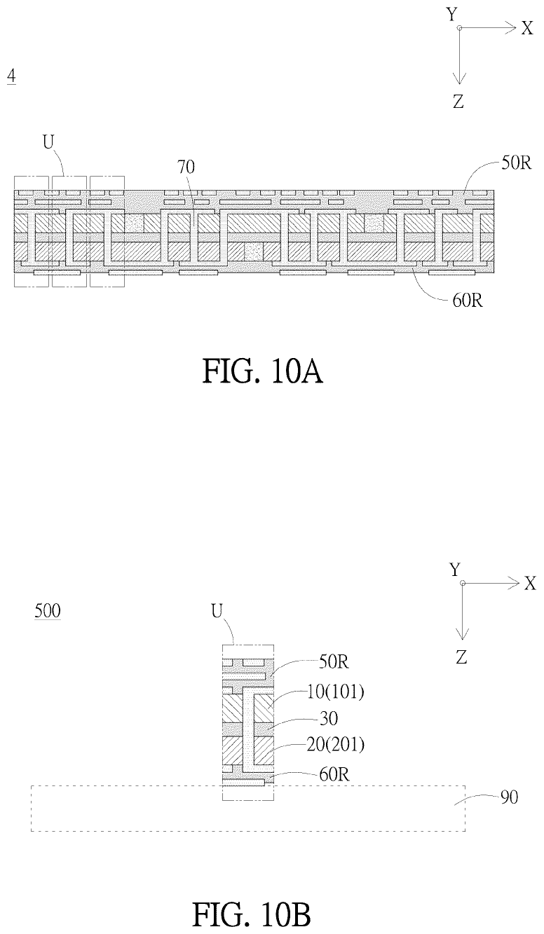

Referring to FIG. 4A, the stacked substrate 2 can be diced to produce multiple dicing units Usub. As shown in FIG. 9, a packaging assembly 400 includes an electrical substrate 90 and a portion of the stacked substrate 2 (i.e., the dicing unit(s) Usub derived from the stacked substrate 2) arranged on the electrical substrate 90; in this case, the electrical layer in the stacked substrate 2 is a single electrical layer. In another embodiment shown by FIG. 10A, the electric layer structure 50R, 60R of the stacked substrate 4 are redistribution layer (RDL) structure, and the stacked substrate 4 can also be diced into dicing units Usub. One or ones of the dicing units Usub derived from the stacked substrate 4 is arranged on the electrical substrate 90 to obtained the packaging assembly shown in FIG. 10B.

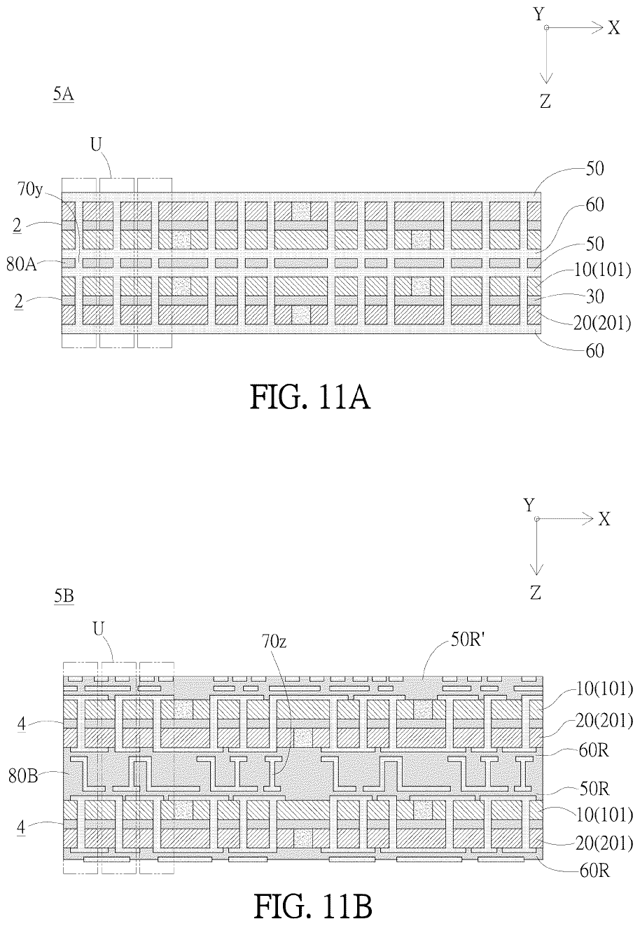

The stacked substrate in this case can be further applied as follows: referring to FIG. 11A, the stacked substrate 5A includes two stacked substrates 2 bonded together by a bonding layer 80A. the second electrical layer structure 60 of the second tiling layer 20/the second tiling substrate 201/of one of the stacked substrates 2 is electrically connected to the first electrical layer structure 50 of the first tiling layer 10/the first tiling substrate 101 of the other stacked substrate 2 by a plurality of conductive through holes 70y. The types and the materials of the bonding layer 80 can be referred to descriptions of the bonding layer 30. In another embodiment, the stacked substrate 5B in FIG. 11B comprises two stacked substrate 4 connected by a bonding layer 80B, the second electrical layer structure 60R of the second tiling layer 20/the second tiling substrate 201/of one of the stacked substrates 4 is electrically connected to the first electrical layer structure 50R of the first tiling layer 10/the first tiling substrate 101 of the other stacked substrate 4 by a plurality of conductive through holes 70z.

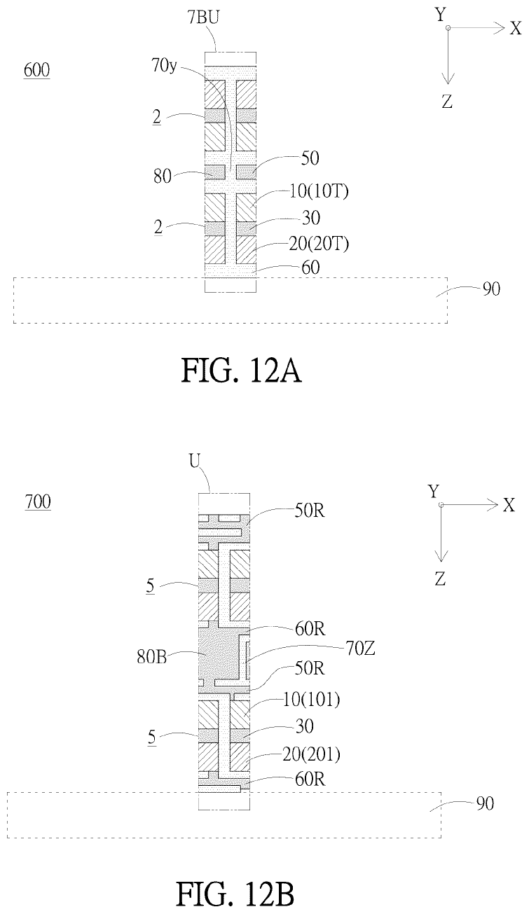

Referring to FIG. 12A, the packaging assembly 600 comprises an electrical substrate 90 and a portion of the stacked substrate 5A (one or ones of the dicing units Usub derived from the stacked substrate 5A) on the electrical substrate 90. The packaging assembly 700 in FIG. 12B comprises an electrical substrate 90 and a portion of the stacked substrate 5B (one or ones of the dicing units Usub derived from the stacked substrate 5B) on the electrical substrate 90; in this embodiment, the first and the second electrical layer structure 50R, 60R are redistribution layer (RDL) structure whose line width is gradually changed from small to large. Further, the conductive through holes 70z at least electrically connect the first and the second electrical layer structure 50R, 60R, or further connect the two corresponding surfaces of the two stacked substrates 5B, but not limiter thereto. The stacked substrate of this disclosure is to provide a large-sized substrate that can be subsequently cut into dicing units with smaller size to serve as high functional substrates for advanced packaging. Some high-performance substrates nowadays cannot applied to a process for manufacturing large-sized circuit since the substrate size thereof is limited so as to increase manufacturing costs. Therefore, in this disclosure, the tiling substrates are tiled by an off-set manner to form a larger tiled substrate which can be applied to a process for manufacturing large-sized circuit, then the tiled substrate can be diced according to the requirement, thereby the need of manufacturing of high-performance substrates and lowering the manufacturing cost are satisfied.

Based on the above description, it should be understood that various embodiments of the disclosure have been described in the specification for illustrative purposes, and various modifications can be made without departing from the scope and spirit of the disclosure. Therefore, the various embodiments of the disclosure are not intended to limit the true scope and spirit of the invention.

The above descriptions are exemplary rather than restrictive. Any equivalent modifications or changes made without departing from the spirit and scope of this invention should be included in the appended patent claims.

What is claimed is:

1. A stacked substrate comprising:
a first tiling layer, including a plurality of first tiling substrates adjacent by one another and a plurality of first gaps formed between adjacent two of the first tiling substrates; wherein each of the first tiling substrates defines a first surface and a second surface opposite to each other;
a second tiling layer, including a plurality of second tiling substrates adjacent to each other and a plurality of second gaps formed between adjacent two of the second tiling substrates; wherein each of the second tiling substrates defines a first surface and a second surface opposite to each other; and
a bonding layer, arranged between the first tiling layer and second tiling layer and defines a first bonding surface and a second bonding surface, wherein the first bonding surface thereof connects to the second surface of the first tiling substrates, and the second bonding surface thereof connects to the first surface of the second tiling substrates;
wherein some projections of at least some of the first gaps and some of the second gaps are offset from each other along a direction perpendicular to the first bonding surface, the second bonding surface, or both of the bonding layer.

2. The stacked substrate of claim 1, wherein the first tiling substrates and the second tiling substrates respectively define one or ones edges, wherein one or ones edges of one of the first tiling substrates approaches to one or ones edges of the corresponding second tiling substrate.

3. The stacked substrate of claim 1, wherein the first tiling substrates and/or the second tiling substrates comprise silicon dioxide (SiO₂), glass, ceramic, compound semiconductor material, or polyimide, or any combination comprising one or ones of the above-mentioned materials.

4. The stacked substrate of claim 1, wherein the first tiling substrate and/or the second tiling substrate defines a thermal conductivity coefficient no less than 1.0 W/m*K.

5. The stacked substrate of claim 1, wherein the first tiling substrate and/or the second tiling substrate defines an elastic modulus no less than 50 GPa.

6. The stacked substrate of claim 1, wherein the first tiling substrate of the first tiling layer defines a first thickness, wherein the first surfaces, the second surfaces, or both of two adjacent first tiling substrates defines a height difference therebetween along a direction perpendicular to the first surface, the second surface, or both, wherein the height difference is no greater than 1/10 of the first thickness of the adjacent two first tiling substrates, or the height difference is not greater than 10 μm.

7. The stacked substrate of claim 1, wherein the second tiling substrate of the second tiling layer defines a second thickness, wherein the first surfaces, the second surfaces, or both of two adjacent second tiling substrate defines a height difference therebetween along a direction perpendicular to the first surfaces, the second surfaces, or both of the second tiling substrates, and wherein the height difference is no greater than 1/10 of the second thickness of the adjacent two second tiling substrates, or the height difference is no greater than 10 μm.

8. The stacked substrate of claim 1, wherein the first tiling substrates define a first thickness and the second tiling substrates define a second thickness; wherein the second thickness no less than 0.8 times and no greater than 1.25 times of the first thickness.

9. The stacked substrate of claim 1, wherein the bonding layer defines a thermal conductivity no less than a thermal conductivity of the first and second tiling substrates.

10. The stacked substrate of claim 1, wherein a ratio of a thermal conductivity of the bonding layer to a thermal conductivity of the first, the second tiling substrates, or both is no less than 1:2.

11. The stacked substrate according to claim 1, wherein the bonding layer defines a bonding layer thickness, the first tiling substrate defines a first thickness, and the second tilling substrate defines a second thickness, and the bonding layer thickness is no greater than 1/10 of the first thickness of the first tiling substrates, 1/10 of the second thickness of the second tiling substrate, or 1/10 of the first thickness and the second thickness.

12. The stacked substrate according to claim 1, wherein the bonding layer defines a bonding layer thickness, and the bonding layer thickness is no greater than 50 μm.

13. The stacked substrate of claim 1, further including a gap filling material arranged in at least some of the first gaps and the second gaps.

14. The stacked substrate of claim 13, wherein the gap filling material defines an elastic modulus less than an elastic modulus of the first tiling substrates or second tiling substrates.

15. The stacked substrate of claim 1, further defining a plurality of tiling units; wherein each of the tiling units is surrounded by some of the first gaps and some of the second gaps, wherein each of the tiling unit is free of the first gaps and the second gaps, and the tiling unit dose not comprises the first gaps or the second gaps therein, and wherein each of the tiling units includes one or ones of dicing units.

16. The stacked substrate of claim 1, wherein an area difference of two areas of at least one of the first tiling substrates at two laterals where the first tiling substrates across a corresponding second gap is no greater than 10%.

17. The stacked substrate of claim 1, wherein the first tiling substrates define a first coefficient of thermal expansion, the second tiling substrates define a second coefficient of thermal expansion; wherein a difference of the first coefficient of thermal expansion and second coefficient of thermal expansion is not greater than 5 ppm/K.

18. The stacked substrate according to claim 1, wherein the first gap defines a first width, the second gap defines a second width, and the first width, the second width, or both is no less than 50 μm.

19. A packaging assembly, comprising:
a portion of the stacked substrate of claim 1; wherein the stacked substrate defines a plurality of tiling units, each of the tiling units is surrounded by some of the first gaps and some of the second gaps and the tiling unit does comprises the first gaps and the second gaps therein; each of the tiling units includes one or ones dicing units; wherein the portion of the stacked substrate at least includes one or ones of the dicing units.

20. The packaging assembly according to claim 19, wherein the tiling unit(s) define(s) an area no less than 5000 mm².

21. The packaging assembly according to claim 19, wherein the dicing unit(s) define(s) an area no less than 5000 mm².
